(19) United States
(12) Patent Application Publication
(10) Pub. No.: US 2008/0001244 A1
(43) Pub. Date: Jan. 3, 2008

(54) System Comprising an Electrical Component and an Electrical Connecting Lead for Said Component, and Method for the Production of Said System

(76) Inventor: Herbert Schwarzbauer, Munchen (DE)

Correspondence Address: STAAS & HALSEY LLP, SUITE 700, 1201 NEW YORK AVENUE, N.W., WASHINGTON, DC, 20005, US

(21) Appl. No.: 10/590,901

(22) PCT Filed: Jan. 19, 2005
(86) PCT No.: PCT/EP05/50218

§ 371 Date: Jul. 12, 2007

(30) Foreign Application Priority Data
Feb. 26, 2004 (DE) 10 2004 009 296.5

(51) Int. Cl. H01L 31/00

(52) U.S. Cl. 257/452

(57) ABSTRACT

A system has at least one electrical component that is provided with at least one electrical contact surface, at least one electrical connecting lead for electrically contacting the contact surface of the component, and at least one electrical insulating layer which is disposed on the component and encompasses at least one opening. The opening is continuous in the direction of the thickness of the insulating layer and is arranged so as to lie opposite the contact surface of the component. The insulating layer is provided with a lateral surface that delimits the opening while the electrical connecting lead is provided with at least one metallization layer located on the lateral surface. The metallization layer is oriented at an angle to the contact surface such that a section of the connecting lead which is mounted on the insulating layer largely disconnects the insulating layer and the component from each other in a mechanical manner. For this purpose, the metallization layer is preferably a few μm think. The mechanical disconnection allows the connecting lead, the insulating layer, and the component to be made of materials having different thermal expansion coefficients.

### CROSS REFERENCE TO RELATED APPLICATIONS

This application is based on and hereby claims priority to PCT Application No. PCT/EP2005/050218 filed on Jan. 19, 2005 and German Application No. 10 2004 009 296.6 filed on Feb. 26, 2004, the contents of which are hereby incorporated by reference.

### BACKGROUND OF THE INVENTION

The invention relates to a system comprising at least one electrical component that is provided with at least one electrical contact surface.

A system and a method for the production of said system are known from WO03/030247 A2 for example. The component is a power semiconductor component, which is located on a substrate (circuit carrier). The substrate is, for example, a DCB (Direct Copper Bonding) substrate, which includes a ceramic carrier layer, to which electrically conducting layers of copper are applied on both sides. The power semiconductor component is soldered onto one of the electrically conducting layers of copper so that there is an electrical contact surface of the power semiconductor component pointing away from the substrate.

An insulating foil with a polyimide or epoxy base is laminated under vacuum onto said system comprising a power semiconductor component and a substrate, so that the insulating foil is closely connected with the power semiconductor component and the substrate. The insulating foil is connected to the power semiconductor component and the substrate to form a positive and non-positive fit. A surface contour (topography), which is produced by the power semiconductor component and the substrate, is mapped in a surface contour of the insulating foil facing away from the power semiconductor component.

For electrically contacting the contact surface of the power semiconductor component, an opening (window) is made in the insulating foil. The opening is made by laser ablation. When this is done, the contact surface of the power semiconductor component is exposed. For the production of the electrical connecting lead by which the contact surface of the power semiconductor component is contacted, a metallization layer is subsequently applied to both the contact surface and the insulating foil. In order to allow a necessary current carrying capacity of the connecting leads generated in this way, a relatively thick layer of copper is deposited onto the metallization layer. Copper is electrodeposited. A layer thickness of the layer of copper can be several hundred μm.

The power semiconductor component may be formed of silicon. There is a clear distinction between a thermal expansion coefficient of copper and the thermal expansion coefficient of silicon. This means that very high mechanical stresses within the system comprising a power semiconductor component and a connecting lead can occur during operation of the power semiconductor component, there can be These high mechanical stresses can lead to interruption of the electrical contact between the connecting lead and the contact surface of the power semiconductor component.

A method for large-area contacting of the contact surfaces of a semiconductor component is also known from Liang et al., Electronic Components and Technology Conference, 2003, pp. 1090 to 1094.

### SUMMARY OF THE INVENTION

Therefore, one possible object of the present invention is to provide a system comprising an electrical component and an electrical connecting lead in which the component and the connecting lead are made of materials having greatly varying thermal expansion coefficients and for which contacting of the contact surface of the component is guaranteed despite of the high thermal stressing of the system.

One possible object is achieved by specifying a system comprising at least one electrical component that is provided with at least one electrical contact surface, at least one electrical connecting lead for electrically contacting the contact surface of the component and at least one electrical insulating layer, which is disposed on the component and encompasses at least one opening. Said opening is continuous in the direction of the thickness of the insulating layer and is arranged so as to lie opposite the contact surface of the component. The insulating layer is provided with a lateral surface that delimits the opening while the electrical connecting lead is provided with at least one metallization layer located on the lateral surface. The system is characterized in that the metallization layer is oriented at an angle to the contact surface. The metallization layer is applied to both the contact surface of the component and the lateral surface of the insulating layer.

The inventor proposes a method for the production of said system with the following procedural steps: a) providing a component with an electrical contact surface, b) producing an insulating layer on the component that encompasses at least one continuous opening so that the contact surface of the component is freely accessible, and c) locating the metallization layer of the connecting lead on a lateral surface of the insulating layer that delimits the opening in such a way that the metallization layer is oriented at an angle to the contact surface.

In order to provide the component with the contact surface, a component is for example arranged in such a way on a substrate that the contact surface of the component is freely accessible. The substrate is any circuit arrangement carrier with an organic or an inorganic base. Such circuit arrangement carriers or substrates are, for example, PCB (Printed Circuit Board) substrates, DCB substrates, IM (Insulated Metal) substrates, HTCC (High Temperature Cofired Ceramics) and LTCC (Low Temperature Cofired Ceramics) substrates.

The connecting lead, for example, has two sections permanently connected to one another. A first section is formed by the metallization layer, which is for example disposed on a beveled lateral surface of the opening and on the contact surface of the component. A second section of the connecting lead is formed by a metallization applied to the insulating layer. By orienting the metallization layer, which is disposed on the lateral surface, the second section of the connecting lead and the component are disconnected from each other in a mechanical manner. This means that the second section of the connecting lead and the component can be fabricated from materials having different thermal expansion coefficients. For example, the second section of the connecting lead has a thick copper layer. The component for example is a semiconductor component of silicon. A very high thermal load of the system results in a very high mechanical load of the system because of the different thermal expansion coefficients. Because copper expands more than silicon, it could, without suitable countermeasures, result in a high tensile load on the first section of the connecting lead or the connection of the connecting leads to the contact surface. However, because of the embodiment of the first section of the connecting lead with the metallization layer which is oriented at an angle to the contact surface, there is an effective strain relief. A likelihood of failure of the system because of the different thermal expansion coefficients of the materials used is greatly reduced. The same also applies especially to an insulating layer with a beveled lateral surface, to which the metallization layer has been applied. In this case, said beveled lateral surface largely decouples a thermal expansion of the insulating layer from the thermal expansion of the sections of the connecting leads.

In a particular embodiment, the metallization layer is oriented at an angle to the contact surface, which is selected from the range from 30° up to and including 80°. The angle is preferably selected from the range from 50° up to and including 70°. At an angle of 90°, the metallization layer would be aligned perpendicular to the contact surface.

The layer thickness of the metallization layer has been selected in such a way that said thickness results in an efficient strain relief. It is especially advantageous if the layer thickness of the metallization layer has been selected from the range from 0.5 μm up to and including 30 μm. The layer thickness has above all been selected from the range from 2.0 μm up to and including 20 μm. A range of the metallization layer, which has not been oriented at an angle to the contact surface, clearly has thicker layers. These thicker layers are for example needed in order to provide a current carrying capacity required for operating the component.

The metallization layer can include only one layer. A one-layer metallization layer is provided. The metallization layer in particular has a multi-layered structure with at least two partial metallization layers arranged one upon the other. In this case, each partial metallization layer is associated with different functions. A first partial metallization layer for example brings about a very high adhesion to the contact surface of the component. This partial metallization layer functions as an intermediate adhesive layer. In the case of a semiconductor component, an intermediate adhesive layer of titanium has proven useful. Other suitable materials for the intermediate adhesive layer are for example chromium, vanadium or zirconium. A second metallization layer arranged over the intermediate adhesive layer for example functions as a diffusion barrier. Such a partial metallization layer may be formed of a titanium tungsten alloy. A third partial metallization layer may be formed copper electrodeposited on the second partial metallization layer. The partial metallization layer of copper takes care of a required current carrying capacity. This results in a metallization layer with the layer sequence Ti/TiW/Cu.

For the metallization layer oriented at an angle, the lateral surface of the opening of the insulating layer has for example been beveled. For example, a (averaged) surface normal of the lateral surface and the (averaged) surface normal of the contact surface take on an angle which has been selected from the range from 30° up to and including 80°. In the case of the averaged surface normals, a roughness or undulation of the surfaces is not taken into account.

In a particular embodiment, the lateral surface of the opening of the insulating layer, on which the metallization layer is located, has at least one step. The step results in an expansion direction of the metallization layer oriented at an angle to the contact surface of the component. Advantageously, there are several steps in this case. The result of the step or the steps is an efficient strain relief.

The single steps are for example produced by a multi-layered insulting layer. Therefore, in a particular embodiment, the insulating layer has a multi-layered structure with at least two partial insulating layers arranged one on top of the other. Therefore, it is possible that one insulating layer or all the partial insulating layers are oriented at an angle to the opening. The insulating layer or the partial insulating layers are for example beveled by removing material by laser ablation. The material can also be removed chemically, wet or dry. For example, insulating material of the partial insulating layers is etched away by exposing it to a reactive substance. Because exposed places, for example, an edge are usually subjected to a higher etching rate, a flattening or a beveling of the partial insulating layers at these edges occurs automatically.

In a further embodiment, a layer thickness of the insulating layer has been selected from the range from 20 μm up to and including 500 μm. The layer thickness of the insulating layer has preferably been selected from the range from 50 μm up to an including 200 μm. If the metallization layer is very thin (for example, 5 μm up to 10 μm), an insulating layer with the clearly thicker layers can function as the efficient abutment. The insulating layer is not pushed away in the case of a thermal expansion of the metallization layer.

In order to produce the insulating layer, an electrically insulating resist is for example applied to a corresponding thickness. The resist is applied to the component by a compressed air process. After the resist has hardened and/or dried, an opening is made in the resulting insulating layer. In this case, photolithography is above all implemented. For this purpose, a photo-resist is preferably used.

In a particular embodiment, the following procedural steps are implemented for the production of the insulating layer on the component: d) laminating at least one insulating foil onto the component and e) producing an opening in the insulating foil so that the contact surface of the component is exposed. The insulating layer is formed by laminating at least one insulating foil onto the component. In this case, at least one part of the insulating foil has been laminated onto the component in such a way that a surface contour of the component is mapped in a surface contour of one part of the insulating foil that has been turned away from the component. The surface contour does not relate to the roughness or the undulation of the surface of the component. The surface contour is for example obtained from an edge of the component. The mapped surface contour is especially not only specified by the component, but also by the substrate on which the component is arranged.

In a particular embodiment, the insulating foil is laminated-on under vacuum. Said lamination under vacuum allows a particularly secure and close contact between the insulating foil and the component to be made.

Only an insulating foil with corresponding foil strength can be laminated-on in this case. However, it is also possible to laminate-on a plurality of insulating foils with corresponding foil strengths on top of each other, which as partial insulating layers together form the insulating layer. An insulating foil used features an electrically-insulating synthetic material. In this case the term synthetic material might include any duroplastic (duromers) and/or thermoplastic synthetic materials. In particular, the insulating foil has at least one synthetic material selected from the polyacrylate, polyimide, polyisocyanate, polyethylene, polyphenol, polyetheretherketone, polytetrafluor ethylene and/or the epoxy group. Mixtures of synthetic materials and/or copolymerisates of monomers of synthetic materials can likewise be considered. So-called Liquid Crystal Polymers can be used in the same way as organically modified ceramics.

In principle, it is possible to laminate insulating foils with openings, which have already been made in the contact surface of the component. For this purpose, the insulating foil is laminated in such a way that the opening lies across the contact surface of the component. However, the openings in the insulating foils are only made after the lamination process in an advantageous way. The opening in the insulating foils is made by the removal of material. This can take place by photolithography. Above all, the opening in the insulating foil is made by laser ablation. Material is removed by using a laser. For the laser ablation, a CO₂ laser with a wave length of 9.24 μm is for example used. The use of a UV laser can likewise be considered.

In order to apply the metallization layer, a vapor deposition method is preferably used. The vapor deposition method is for example a physical vapor deposition method (Physical Vapor Deposition, PVD). Such a vapor deposition method can also be used for producing the insulating layer. The PVD method is for example sputtering. A chemical vapor deposition method (Chemical Vapor Deposition, CVD) can likewise be considered. Especially in the case of a beveled lateral surface of the opening of the insulating layer, it is possible to produce a metallization layer with a sufficient layer thickness by using a vapor deposition method. In an advantageous way, the vapor deposition method also allows a metallization layer to be applied to the insulating layer or the insulating foil, which is for example the starting point for electrodepositing additional electrode material. In an advantageous way, for the metallization layer and/or the electrodeposition, a metal is selected from the aluminum, the gold, the copper, the molybdenum, the silver, the titanium and/or the tungsten group. In this case, silver is particularly suitable because it has a high electrical conductivity and at the same time is relatively soft (lower e-module than copper). In this way, there are lower mechanical stresses when it is subjected to a thermal load.

In a further embodiment, before and/or after the application of the metallization layer to the lateral surface, a section of the connecting lead is produced on the insulating layer, the thickness of which exceeds the layer thickness of the metallization layer. For example, a thin metallization layer is not only applied to the lateral surface of the insulating layer up to the opening of the insulating layer, but also to the surface of the insulating layer. A metal is electrodeposited on the metallization layer on the surface of the insulating layer. The section of the connecting lead with the thicker layer is formed in this case. By doing so, the metal is deposited with a layer thickness of up to 500 μm. The metal is for example aluminum or copper.

In order to produce the section of the connecting lead with the thick layer, the opening of the insulating layer is preferably closed while the metal is deposited.

In order to close the opening, a photolithographic process is performed for example. The closing of the opening guarantees that the metal is only deposited on those places of the connecting lead, which are not covered.

The system can feature any component. The component is for example a passive electrical component. In a particular embodiment, the component is a semiconductor element. The semiconductor element is preferably a power semiconductor component. The power semiconductor component is selected especially from the diode, the MOSFET, the IGBT, the thyristor and/or the bipolar transistor group. Such power semiconductor components are suitable for controlling and/or switching high currents (a few hundred A).

The above-mentioned power semiconductor components are controllable. To this end, the power semiconductor components in each case have at least one input contact, one output contact and a control contact. In the case of a bipolar transistor, the input contact is usually called an emitter; the output contact a collector and the control contact the base. In the case of a MOSFET, these contacts are called a source, a drain and a gate.

Particularly in the case of a power semiconductor component, very high currents are switched during operation, so that a considerable development of heat results. Because of the development of heat, it is possible particularly in the case of the power semiconductor components which are electrically contacted via thick connecting leads of copper for the above-described mechanical stresses to be caused in this case. The embodiment of the connecting lead with the relatively thin metallization layer oriented at an angle to the contact surface of the power semiconductor component allows an efficient strain relief to be implemented.

In the case of power semiconductor components, it is important that a corresponding contact surface be supplied with sufficient current. In order to guarantee this, in a particular embodiment, the insulating layer has a plurality of openings, which form one row or a matrix. A large-area contacting of the contact surface is in each case achieved with at least one metallization layer via the plurality of openings. This guarantees that the power semiconductor component, despite thin metallization layers is supplied with sufficient current. In addition, care has been taken that the current is also distributed evenly across the contact surfaces. During the operation of the power semiconductor component, no interfering lateral current gradient occurs in the contact area.

In the case of a matrix, openings with a more or less symmetrical surface area in the insulating layer for example are present. The surface area is for example oval, rectangular or circular. For openings arranged in rows, openings with a lamellar surface area are offered. The metallization layers are preferably applied along one longitudinal edge or along both longitudinal edges of each of the lamellar openings.

In summary, the following significant advantages are obtained with system and method:
The embodiment of the connecting lead with the preferably thin metallization layer oriented at an angle to the contact surface of the component allows a section of the connecting lead, which is applied to the insulating layer and the component to be largely decoupled mechanically.
The mechanical decoupling greatly reduces a probable failure of the system because of thermally induced mechanical stresses. The same also applies especially to the case in which the connecting lead and the component are formed of different materials having different expansion coefficients.
The system is especially advantageous for electrically contacting power semiconductor components which generate a relatively large amount of heat during operation.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows a system comprising an electrical component, a connecting lead of the component and an insulating layer on a substrate in a side cross-section.

FIG. 2 shows a section of the system from FIG. 1.

FIGS. 3 to 5 show different embodiments of the system.

FIG. 6 shows from above a section of an insulating layer with a matrix of a plurality of openings.

FIG. 7 shows from above a section of an insulating layer with a row of a plurality of lamellar openings.

FIG. 8 shows a method for the production of said system.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

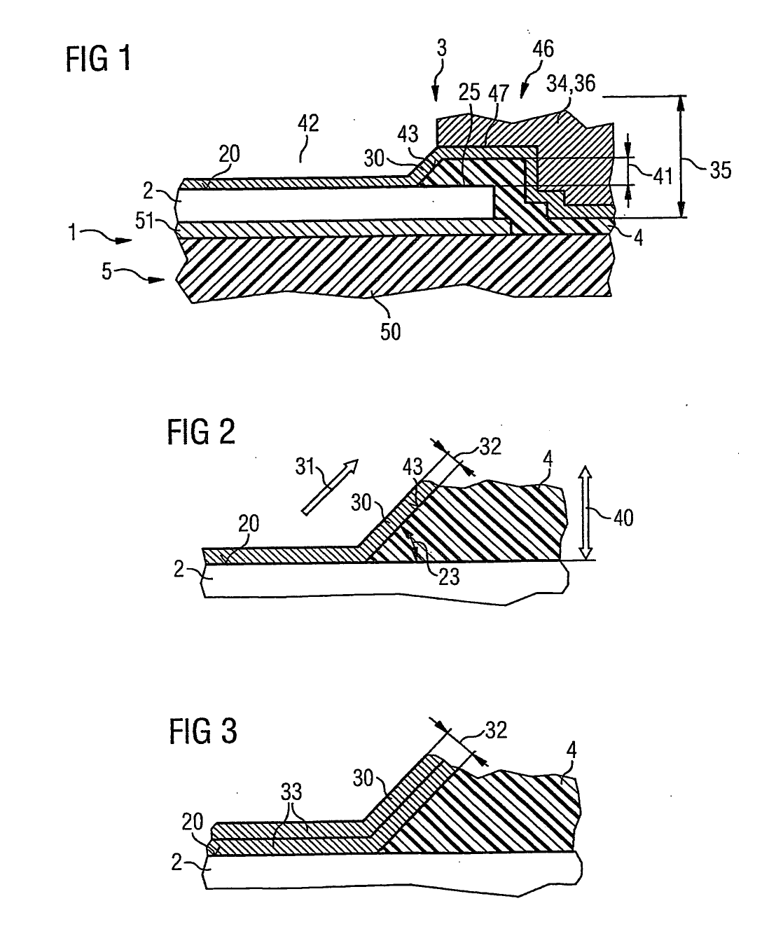

System 1 features an electrical component 2 on a substrate 5 (FIG. 1). The substrate 5 is a DGB substrate with a carrier layer 50 and an electrically-conducting layer 51 of copper applied to the carrier layer 50. The carrier layer 50 is formed of a ceramic material.

The electrical component 2 is a power semiconductor component in the form of a MOSFET. The power semiconductor component 2 has been soldered onto the electrically-conducting layer 51 in such a way that an electrical contact surface 20 of the power semiconductor component 2 faces away from the substrate 5. One of the contacts of the power semiconductor component 3 (source, gate, drain) is electrically contacted over the contact surface 20.

An insulating layer 4 in the form of an insulating foil is applied to the power semiconductor component 2 and to a substrate 5. In this case, the insulating foil 4 is applied in such a way that a surface contour 25, which results from the power semiconductor component 2, the electrically-conducting layer 51 and the carrier layer 50 of the DCB substrate, is mapped in a surface contour 47 of a part of the insulating foil 4. The insulating foil follows the topology of the power semiconductor component 4 and the substrate 5. In this case, a difference in height exceeding 500 μm is overcome.

The insulating foil 4 has an opening 42, which is continuous in the direction of the thickness 40 of the insulating foil (FIG. 2). Said opening 42 is arranged so as to lie opposite the electrical contact surface 20 of the power semiconductor component 2. The lateral surface 43 of the insulating layer that delimits the opening 42 of the insulating layer is beveled. The lateral surface 43 is oriented at an angle to the contact surface 20.

A metallization layer 30 is applied to the lateral surface 43. A layer thickness 32 of the metallization layer 30 is approximately 5 μm. Based on the beveled lateral surface 43 of the insulating foil 4, the metallization layer 30 is likewise oriented at an angle to the contact surface 20 of the power semiconductor component 2. An angle 23 by which the metallization layer 30 is oriented to the contact surface 20 is approximately 50°.

As an alternative to the one-layer metallization layer 30, the metallization layer 30 can be distinguished by a multi-layered structure (FIG. 3). The metallization layer 30 may be formed of individual, partial metallization layers 33 arranged on top of each other. A total layer thickness 30 is likewise 5 μm. The bottom partial metallization layer, which is directly connected to the contact surface 20 of the power semiconductor component, may be formed of titanium and functions as an adhesive layer. The partial metallization layer arranged over that may be formed of a titanium tungsten alloy.

A section 34 of the connecting lead 3 is applied to the area 46 of the insulating foil 4, said section having a thicker layer 35 than a layer thickness 32 of the metallization layer 30 in the opening 42 of the insulating foil 4. The thickness 35 of the connecting lead 3 in section 34 is approximately 500 μm. This section is formed by an electrodeposition 36 of copper.

The power semiconductor component 2 is made of silicon. The section 34 of the connecting lead 3 on the insulating foil 4 is made of copper. During the operation of the power semiconductor component 2, very high currents flow. Because of the dissipation loss of the power semiconductor component 2, a relatively high heating of the entire system 1 is produced. Because silicon and copper have greatly differing thermal expansion coefficients, relatively high mechanical stresses may develop within system 1. Therefore, there is a relatively high tensile stress in the direction of the thickness of the electrodeposited layer 36 of copper. The specially selected system comprising a connecting lead 3 with a thin metallization layer 30 in opening 42 of the insulating foil 4 guarantees that the thermally induced expansion of section 34 of the connecting lead 3 and the thermal expansion of the insulating layer 4 are almost disconnected from the thermally-induced expansion of the semi-conductor component 2. In essence, section 34 of the connecting lead and the power semiconductor component 2 are disconnected from each other in a mechanical manner. Therefore, the metallization layer 30 oriented at an angle to the opening causes a strain relief of system 1. This results in a higher reliability of system 1. Via the metallization layer 30, the power semiconductor component 2 remains electrically contacted despite a high thermal load.

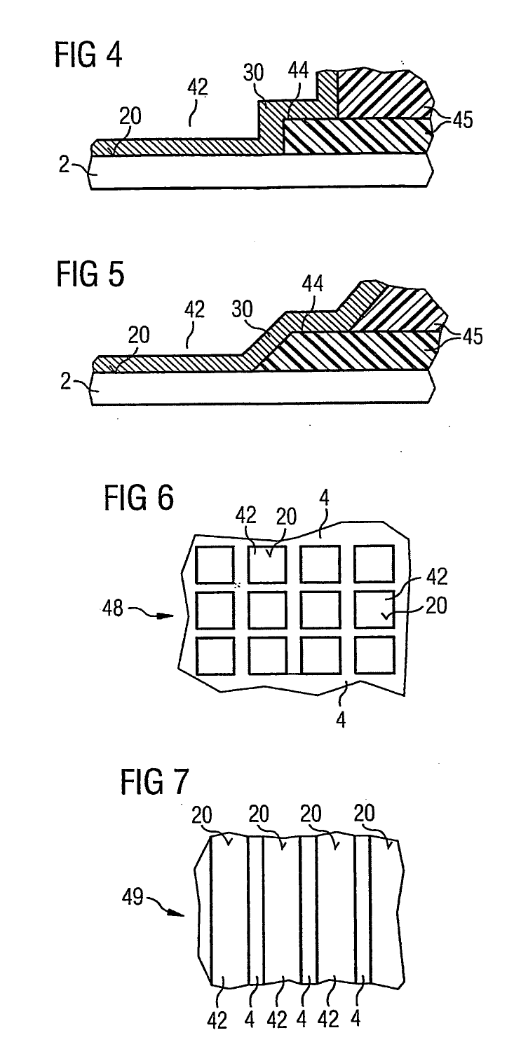

In a further embodiment, the insulating foil 4 has a plurality of partial insulating foils 45 (FIG. 4). The insulating foil 4 may be formed of several partial insulating foils 45 arranged above one another. In this case, the partial insulating foils 45 are arranged in such a way that there is a step 44 in opening 42. The metallization layer 30 is applied to said step 44. Step 44 acts as strain relief. In addition, in a further development of this embodiment each partial insulating foil 45 is beveled (FIG. 5).

In order to guarantee a flow of current needed for the operation of the power semiconductor component 2, a plurality of openings 42 of such a kind are arranged across the contact surface 20 of the power semiconductor component 2. In this case, the plurality of openings 42, form a row 49 (FIG. 7). Each of the openings 42 has a lamellar surface area. In a further embodiment, each opening 42 has a square surface area. The plurality of openings 42 are distributed in the form of a matrix 48 across the insulating foil 4 (FIG. 6). In this case, each of the openings 42 is arranged in such a way that the contact surface 20 is electrically contacted each time through the opening 42 by a metallization layer 30. On the one hand, said system 1 guarantees a necessary current carrying capacity. In addition it is guaranteed that the contact surface 20 of the power semiconductor component is evenly supplied with current.

As an alternative, in an embodiment (not shown) for the provision of a necessary flow of current on the metallization layer which is located directly over the contact surface, a relatively thick copper layer is applied. This copper layer is for example applied to the center of the opening 42.

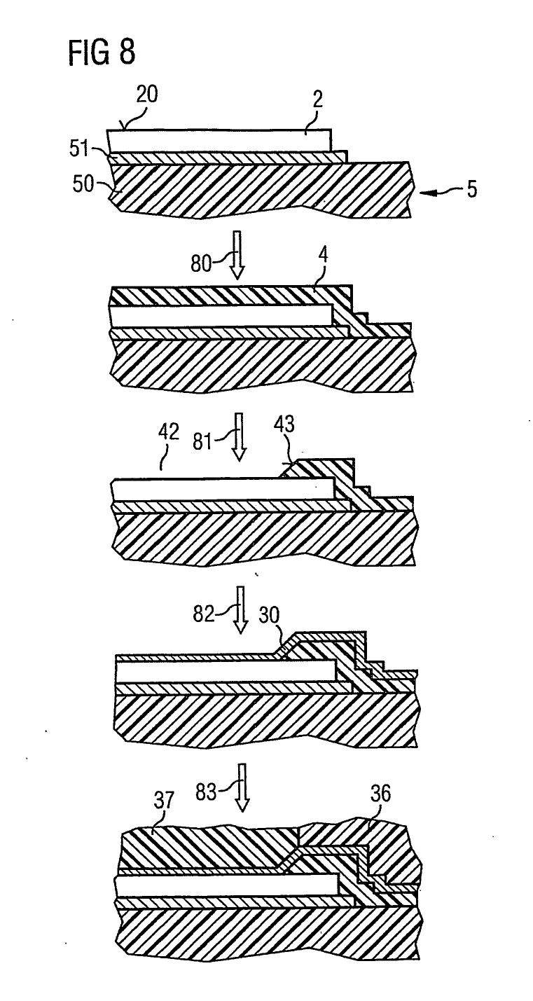

For the production of said system 1, the power semiconductor component 2 is soldered onto a DCB substrate 5. The insulating foil 4 is then laminated onto it (FIG. 8, reference symbol 80). The lamination is carried out under vacuum. This allows a particularly secure and close contact between the insulating foil 4 and the power semiconductor component 2 or the substrate 5. The lamination process allows the surface contour 25, which is determined by the power semiconductor component 2 and the substrate 5 to be shown in the surface contour 47 of the insulating foil 4. A surface of the insulating foil 4 turned away from the substrate 5 and the power semiconductor component 2 in essence has the same surface contour as the power semiconductor component 2 and the substrate 5.

In the next procedural step (FIG. 8, reference symbol 81), the opening 42 for contacting the contact surface 20 of the power semiconductor component 2 is made in the insulating foil 4. A window 42 is opened. The window 42 is opened by the removal of material by laser ablation. For this purpose, a 002 laser with a wave length of 9.24 μm is used. In this case, material is removed in such a way that a lateral surface 43 oriented at an angle to the contact surface 20 of the power semiconductor component 2, delimiting the opening 42 is obtained. A cleaning step is carried out after the removal of material in order to remove residues resulting from the said removal of material.

After the opening 42 has been made, a metallization layer 30 is applied to the contact surface 20 of the power semiconductor component 2, the lateral surface 43 of the insulating foil 2 and the surface of the area 46 of the insulating foil 4 (FIG. 8, reference symbol 82). The application is executed by a vapor deposition method. The method is carried out several times, if required, in order to obtain a metallization layer with a multi-layered structure.

In addition, the opening 42 is covered in a photolithography step (FIG. 8, reference symbol 82). This results in a sealing 37 of the connecting lead 3 or the metallization layer 30 in the opening 42. Copper is then electrodeposited for the production of said connecting lead 3 in the non-sealed area. This results in section 34 of the connecting lead 3 being covered with a thicker copper layer. A layer thickness 35 of the copper layer 36 is 400 μm.

As an alternative to the method described above, an electrodeposition is carried out on both the metallization layer 30 in the opening 42 and the metallization layer outside the opening 42.

The electrodeposition is interrupted. The opening 42 is then sealed in a photolithography step. In addition, in the area outside the opening 42, copper is deposited in a corresponding thickness. This results in a metallization layer 30 with an additional partial metallization layer 33 of copper.

In a further embodiment, the provision of the power semiconductor component 2 with a metallization layer 30 on the contact surface 20 is carried out as follows: The insulating foil 4 is laminated onto a wafer, which is divided into a plurality of power semiconductor components 2. In addition, the contact surfaces 20 of the power semiconductor component 2 are exposed. A metallization of the contact surfaces 20 and the insulating foil 4 is then carried out in each case. A metallization layer 30 is deposited in the openings 42 of the insulating foil and on the insulating foil 4 as such. The deposition is carried out in a structured manner.

Furthermore the electrical connecting leads, as described above, are produced directly on the wafer. The division into individual modules is only carried out after the production of the electrical connecting leads. As an alternative, the wafer is divided into individual power semiconductor components 2 for this purpose. The individual power semiconductor components 2 are processed further, as described above. For this purpose, one of the power semiconductor components 2 is for example soldered onto a substrate. An additional insulating foil is then laminated onto the power semiconductor component 2 and the substrate 5. Openings are made at the corresponding points in said additional insulating foil. Electrically-conducting material is inserted into these openings.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v DIRECTV, 69 USPQ2d 1865 (Fed. Cir. 2004).

1-26. (canceled)

27. A system comprising:
an electrical component provided with at least one electrical contact surface;
an electrical insulating layer, which is disposed on the component, the electrical insulating layer having an opening to expose and surround a portion of the contact surface, wherein the insulating layer having a lateral surface that delimits the opening; and
an electrical connecting lead for electrically contacting the contact surface of the component, the electrical connecting lead comprising a metallization layer located on the lateral surface, such that the metallization layer meets the contact surface at an angle less than 90 degrees.

28. The system as claimed in claim 27, wherein the metallization layer is oriented at an angle to the contact surface within a range of from 30° to 80°.

29. The system as claimed in claim 27, wherein the metallization layer has a layer thickness within a range of from 0.5 82 m to 30 μm.

30. The system as claimed in claim 27, wherein the metallization layer has a multi-layered structure with at least two partial metallization layers arranged one upon the other.

31. The system as claimed in claim 27, wherein the lateral surface of the insulating layer, on which the metallization layer is located has at least one step.

32. The system as claimed in claim 27, wherein the insulating layer has a layer thickness within a range of from 20 μm to 500 μm.

33. The system as claimed in claim 27, wherein the insulating layer has a multi-layered structure with at least two partial insulating layers arranged one on top of the other.

34. The system as claimed in claim 27, wherein the insulating layer is formed by laminating at least one insulating foil onto the component.

35. The system as claimed in claim 34, wherein
the lateral surface of the insulating layer faces the component,
at least one part of the insulating foil is laminated onto the component in such a way that the insulating layer has a surface contour facing away from the component, and
a surface contour of the component is shown in the surface contour of the insulating foil that faces away from the component.

36. The system as claimed in claim 27, wherein the connecting lead has a section formed of a material different from the metallization layer, which section is located on the insulating layer and is provided with a thickness greater than that of the metallization layer.

37. The system as claimed in claim 36, wherein the section of the connecting lead is electrodeposited.

38. The system as claimed in claim 37, wherein the metallization layer and/or the section is formed of at least one metal selected from the group consisting of aluminum, gold, copper, molybdenum, silver, titanium and tungsten.

39. The system as claimed in claim 36, wherein the component is a semiconductor component.

40. The system as claimed in claim 39, wherein the semiconductor component is a power semiconductor component.

41. The system as claimed in claim 40, wherein the power semiconductor component is a component selected from the group consisting of a diode, a MOSFET, a IGBT, a thyristor and a bipolar transistor.

42. The system as claimed in claim 27, wherein the insulating layer has a plurality of openings arranged in a row or a matrix.

43. The system as claimed in claim 27, wherein the metallization layer is oriented at an angle to the contact surface within a range of from 50° to 70°.

44. The system as claimed in claim 27, wherein the metallization layer has a layer thickness within a range of from 2.0 μm to 20 μm.

45. The system as claimed in claim 27, wherein the insulating layer has a layer thickness within a range of from 50 μm up to an including 200 μm.

46. A method for producing a system comprising:
providing a component with an electrical contact surface;
producing an insulating layer on the component, the insulating layer having an opening to expose and surround a portion of the contact surface of the component so that the contact surface is freely accessible, the insulating layer having a lateral surface that defines the opening; and
locating a metallization layer of a connecting lead on the lateral surface of the insulating layer in such a way that the metallization layer meets the contact surface at an angle less than 90 degrees.

47. The method as claimed in claim 46, wherein the insulating layer is formed by a process comprising:
laminating at least one insulating foil onto the component; and
producing an opening in the insulating foil so that the contact surface of the component is exposed.

48. The method as claimed in claim 47, wherein the insulating foil is laminated under a partial vacuum.

49. The method as claimed in claim 47, wherein the opening in the insulating foil is made by laser ablation.

50. The method as claimed in claim 46, wherein in order to produce the insulating layer on the component, a compressed air process is used wherein a paint is applied to the component.

51. The method as claimed in claim 50, wherein the paint is a photo-sensitive paint.

52. The method as claimed in claim 46, wherein the metallization layer and/or the insulating layer is formed by a vapor deposition method.

53. The method as claimed in claim 46, wherein a section of the connecting lead is formed separately from the metallization layer, the section being produced on the insulating layer to have a thickness which exceeds that of the metallization layer.

54. The method as claimed in claim 53, wherein a metal is electrodeposited to produce the section on the insulating layer.

55. The method as claimed in claim 53, wherein, while the section is being produced, the opening in the insulating layer is closed.
